(19) United States
(12) Patent Application Publication
(10) Pub. No.: US 2025/0048548 A1
(43) Pub. Date: Feb. 6, 2025

(54) ULTRATHIN COMPOSITE DIELECTRICS FOR USE IN PRINTED CIRCUIT BOARDS

(71) Applicant: AVISHTECH, INC., San Jose, CA (US)

(72) Inventors: Tarun Amla, San Jose, CA (US); Keshav Amla, San Jose, CA (US); Jyoti Amla, San Jose, CA (US)

(21) Appl. No.: 18/228,366

(22) Filed: Jul. 31, 2023

(51) Int. Cl. H05K 1/03

(52) U.S. Cl. CPC H05K 1/036; H05K 2201/0129; H05K 2201/0141

(57) ABSTRACT

Dielectric material layers including thermoplastic liquid crystal polymer (LCP) substrates coated or impregnated with a thermosetting resin. The dielectric material layers may have a dielectric constant (DK) value of less than about 3.4 and a dissipation factor of less than about 0.005 for use in printed circuit boards. The dielectric material layers may find particular utility in high density interconnect (HDI) printed circuit boards.

### FIELD OF TECHNOLOGY

Aspects relate generally to printed circuit boards, including high density interconnect (HDI) printed circuit boards, and, more particularly, to dielectrics for use therein.

### BACKGROUND

Thinner dielectrics are needed for next generation products pertaining to chip packaging substrates, mobile devices and communication technologies such as 5G. These thin dielectrics also need to have a low dissipation factor and a low dielectric constant to improve signal integrity. In addition to the thickness requirements, the dielectric materials also need to be easily laser drillable. In the current state of art, glass-reinforced materials are typically used, but these lead to issues with laser drilling, as the glass requires more energy than the polymeric resin to ablate, which leads to poorer hole quality. Additionally, glass-reinforced materials are also limited in the ability to produce very thin dielectrics.

### SUMMARY

In accordance with one or more aspects, a printed circuit board is disclosed. The printed circuit board may comprise at least one dielectric material layer comprising a thermoplastic liquid crystal polymer (LCP) substrate coated or impregnated with a thermosetting resin.

In some aspects, the at least one dielectric material layer may have a dielectric constant (DK) value of less than about 3.4. The at least one dielectric material layer may have a DK value of less than about 3.0. The at least one dielectric material layer may have a DK value of less than about 2.8.

In some aspects, the at least one dielectric material layer may be characterized by a dissipation factor of less than about 0.005. The at least one dielectric material layer may be characterized by a dissipation factor of less than about 0.0025.

In some aspects, the at least one dielectric material layer may have a thickness of less than about 125 microns. The at least one dielectric material layer may have a thickness of less than about 50 microns. The at least one dielectric material layer may have a thickness of less than about 40 microns. The at least one dielectric material layer may have a thickness of less than about 25 microns.

In some aspects, the at least one dielectric material layer may comprise a prepreg or a laminate.

In some aspects, the thermosetting resin may be a crosslinked thermosetting polymer resin selected from the group consisting of: an epoxy resin, a bismaleimide resin, a cyanate ester resin, a BT resin, a polybutadiene resin and a PPE/PPO resin. The thermosetting resin may be a crosslinked thermosetting polymer resin comprising at least one resin selected from the group consisting of: a vinyl functional PPE resin, an OPE resin, a Bismaleimide resin, a Triallyl Cyanurate resin and a Tri Allyl Isocyanurate resin.

In at least some non-limiting aspects, the thermosetting resin may be substantially halogen free.

In some aspects, the thermosetting resin may further comprise at least one of: a flame retardant, a curing agent, a hardener, a filler and an additive.

In some aspects, the at least one dielectric material layer may be copper clad.

In some aspects, the LCP substrate may comprise a polyarylate resin.

In some aspects, the LCP substrate may be characterized by a basis weight of less than about 25 GSM. The LCP substrate may be characterized by a basis weight of less than about 10 GSM.

In some aspects, the at least one dielectric material layer may be characterized by a glass transition temperature (Tg) of greater than about 150° C.

In some aspects, the at least one dielectric material layer may be characterized by a tensile modulus in plane directions of greater than about 5 GPa.

In some aspects, the printed circuit board may be a high density interconnect (HDI) printed circuit board.

Described herein are liquid crystal polymer (LCP) substrate reinforced dielectric material layers with a thermosetting polymeric matrix for use in printed circuit boards and high density interconnect (HDI) printed circuit boards. LCP is a thermoplastic, and the use of thermoplastics in multilayer printed circuit boards has been limited to double sided applications mainly because these materials melt above 290° C. Multilayer boards including HDI boards need to go through multiple pressings or lamination cycles. Since the LCP materials melt at such high temperatures, this is not feasible in most printed circuit board (PCB) shops. Additionally, reliability is adversely affected when going to such high temperatures. In high density interconnect manufacturing the vias are fabricated at each layer and exposure to high temperatures (i.e. greater than about 260° C.) would accelerate via failures. In the present invention, these problems are solved by using a LCP substrate as a reinforcement which is impregnated or coated with a thermoset resin and cured to a B-stage so that it can then be used to form copper clad or unclad laminates and prepregs for use in printed circuit boards.

One aspect of the invention is the use of an LCP substrate, e.g. sheet or fabric, coated or impregnated with a thermosetting resin for use as a single or multiple dielectric material layer in printed circuit boards.

In some embodiments the thickness of the LCP sheet is less than about 50 microns prior to processing and/or pressing.

In some embodiments, the dielectric material layer may or may not be clad with copper.

In preferred embodiments, the Tg of the thermosetting resin is greater than about 150° C.

In some embodiments, the at least one dielectric material layer may have a dielectric constant (DK) of less than about 3.5.

In some embodiments, the thickness of the dielectric material layer may be less than about 15 microns.

In some embodiments, the LCP substrate is based on polyarylate resin.

In some embodiments, the LCP substrate is a sheet.

In some embodiments, the LCP substrate is a nonwoven fabric or veil.

In some embodiments, the LCP substrate has a dissipation factor of less than about 0.005 at 10 GHz.

In some embodiments, the LCP substrate has a dissipation factor of less than about 0.0025 at 10 GHz.

In some embodiments, the dissipation factor of the at least one dielectric material layer comprising thermoplastic LCP with thermosetting matrix material is less than about 0.005 at 10 GHz.

In some embodiments the dissipation factor of the at least one dielectric material layer comprising thermoplastic LCP with thermosetting matrix material is less than about 0.0025 at 10 GHz.

The disclosure contemplates all combinations of any one or more of the foregoing aspects and/or embodiments, as well as combinations with any one or more of the embodiments set forth in the detailed description and any examples.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 presents a schematic of a dielectric material layer for use in printed circuit boards in accordance with one or more embodiments.

### DETAILED DESCRIPTION

Current state of the art thin dielectric material layers for printed circuit boards use either pure thermosetting films or thermoplastic films, which have issues relating to thickness control, handling, stiffness and reliability.

Thermoplastic films or sheets are not suitable for multilayer lamination. The thermoplastic films must have a high melt temperature so that they can be used during PCB processes and assembly in the printed circuit board application. For a thermoplastic material to be usable, the assembly and soldering temperatures cannot exceed its melting point. Given that these processing temperatures are set by choice of the solder, only thermoplastics with sufficiently high melt points can be used. However, this renders these thermoplastic films unsuitable for multilayer boards because board fabrication will require the material to exceed its melting point to bond to other layers. Additionally, for HDI boards requiring sequential laminations, the temperature would have to exceed the melting point multiple times, and this would lead to a number of problems, such as melting and distortion of the circuit layer, and could also lead to what is called circuit swimming wherein the circuit can separate from the substrate. Exposing the circuitry to such high temperatures, especially in the context of high density interconnect (HDI) boards, poses major reliability challenges and therefore thermoplastic films and sheets are not used for multilayer printed circuit boards. There is a need for a low loss, low DK, ultrathin dielectric material layer that can be easily laser drilled and has the right combination of thermo-mechanical properties. Most thermoplastics with high melting points such as PTFE have very poor adhesion, low stiffness, and high expansion, and therefore are not suitable for use as a reinforcement.

In the present invention, the problems are solved through the use of a thermoplastic LCP reinforcing substrate, impregnated or coated with a thermosetting resin, as a dielectric material layer in printed circuit boards.

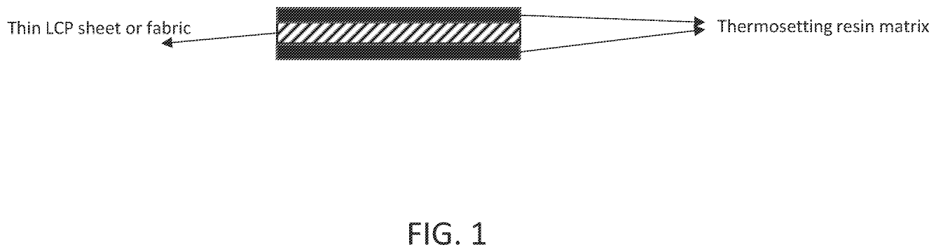

With reference to FIG. 1, a dielectric material layer in accordance with one or more embodiments is presented. The dielectric material layer includes an LCP substrate impregnated with a thermosetting resin matrix.

In some embodiments, a dielectric material layer may be a prepreg or a laminate. The prepeg or laminate may include at least one layer of an LCP substate, e.g. sheet or film. The LCP substrate may be coated or impregnated with a thermosetting resin.

In accordance with one or more embodiments, the prepreg or laminate may have a thickness of less than about 125 microns. In some embodiments, the thickness of the prepreg or laminate may be less than about 50 microns, e.g. less than about 40 microns, less than about 30 microns, less than about 20 microns, or less than about 15 microns.

In some embodiments, the LCP substrate is a non-woven fabric or sheet.

In some embodiments, the thickness of the LCP substrate is less than about 125 microns, e.g. less than about 75 microns or less than about 50 microns prior to processing and/or pressing.

In some embodiments, the basis weight of the LCP substrate is less than about 25 GSM such as <9 GSM, <4 GSM.

In some embodiments the DK of the prepreg or laminate is less than about 3.4, such as less than about 3.0.

In some embodiments the Df of the prepreg or laminate at 10 GHz is less than about 0.005.

In preferred embodiments, LCP substrate commercially available from Kuraray may be used. LCP substrate such as what is supplied by Kuraray has a very low dissipation factor as opposed to other reinforcements such as E Glass and Aramid which have a very high dissipation factor not suitable for ultrahigh speed applications.

In preferred embodiments, the Df of the prepreg or laminate is less than about 0.0025.

In some non-limiting embodiments, the LCP substrate is a Polyarylate resin.

In accordance with one or more embodiments, the dielectric material layer may be characterized by a glass transition temperature (Tg) of greater than about 150° C.

In accordance with one or more embodiments, the dielectric material layer may be characterized by a tensile modulus in the planar directions of greater than about 5 GPa.

In accordance with one or more embodiments, the resin used for impregnating the LCP substate, e.g. fabric or sheet may be a crosslinked thermosetting polymer composition. A wide range of possible resin systems can be used, including but not limited to epoxies, bismaleimides, cyanate esters, BT, polybutadiene, and PPE/PPO. In some embodiments, the polymer system may include at least one resin selected from the group consisting of: a vinyl functional PPE resin, an OPE resin, a Bismaleimide resin, a Triallyl Cyanurate resin and a Tri Allyl Isocyanurate resin.

In some embodiments, the resin system may include one or more hardeners, such as TAIC/TAC, polybutadienes, styrene butadienes, maleic anhydrides and/or amines.

In some embodiments, the resin system may include flame retardants, such as phosphinates, Phosphazene and/or DOPO.

In some embodiments, the resin system may include various fillers and additives, such as Silica, Talc and/or glass microspheres. In some embodiments, the resulting dielectric material may be characterized by a filler content greater than about 20% by weight.

In preferred embodiments the resulting dielectric material layers may be characterized by a filler content greater than about 50% by weight.

In at least some embodiments, the resin system may be substantially halogen free.

In some embodiments, the LCP reinforced dielectric laminates and prepregs can be made using combinations of materials such as vinyl functional PPE available from Sabic corporation such as SA9000, or OPE resins from Mitsubishi chemicals, Bismaleimide resins such as BMI 5100, BMI 2300 available from Daiwa Kasei of Japan or GMI 5100 from Shin A Tec of South Korea, Triallyl Cyanurate or Tri Allyl Isocyanurate available from Evonik corporations. Fillers such as Fused Silica, Talc or air filled microspheres may be used.

In preferred embodiments of the resin, combinations of functionalized PPE and of Triallyl Cyanurate/Triallyl Isocyanurate and/or butadiene styrene polymers such as Ricon 100, Ricon 257 and Polymers of butadiene such as Ricon 134, Ricon 154, Ricon 156, and Ricon 157 available from Total with flame retardants and fillers and a peroxide agent are used. In the preferred embodiment, the curing agent is a peroxide agent. Examples of peroxide curing agents include dicumyl peroxide, Benzoyl peroxide, lauroyl peroxide, 2-Butanone peroxide, and mixtures comprising one or more of the peroxide curing agents. The curing agent is present in an amount of about 0.25 wt. % to about 6 wt. %, based on the total weight of the resin. In some embodiments Spherical Silica, Talc, Hexagonal Boron Nitride, glass filled microspheres are used. Flame retardant such as Exolit® OP935 or Exolit® OP945 Aluminum Poly Phosphinate available from Clariant corporation, SPB 100 or Phosphazene available from Otsuka chemical corporation can also be used as a flame retardant to make the resin substantially halogen free. In some embodiments phosphorated compounds such as Altexia from Albemarle or PQ 60 from Chin Yee chemicals may also be used, alone or in combination with other flame retardants. In halogenated embodiments flame retardants such as Saytex 8010, Ethylene-1,2-bis (pentabromophenyl) or BT 93 from Albemarle corporation can be used.

In optional embodiments, epoxy resins cured with SMA type hardeners may be used with combination of Cyanate esters with accelerators such 2-MI, 2,4 EMI.

In accordance with one or more embodiments, the resin may be filled with Spherical Silica.

In some embodiments, the resin used to coat or impregnate may have a filler content of greater than about 60% by weight.

In some embodiments, the resin may have a filler content of greater than about 50% by weight.

In some embodiments, the resin may have a filler content of greater than about 40% by weight.

In some embodiments, the resin may have a filler content of greater than about 20% by weight.

The resin used for coating or impregnation is low loss and low Dk so as to impart a low dissipation factor and a low dielectric constant. Resins comprising of PPE, Styrene Butadiene type systems can be used. In some embodiments, the neat resin has a DK value of less than about 3.5. In preferred embodiments, the DK of the neat resin is less than about 3.0. In some embodiments the DK of the neat resin is less than about 2.5. The Dissipation factor of the neat resin may be less than about 0.010 in some embodiments. In preferred embodiments the Df of the resin is less than about 0.005. In some embodiments the DF of the resin is less than about 0.0025.

In some embodiments, provided herein are methods of manufacturing a sheet of dielectric material. In a preferred embodiment, the LCP substrate is fully impregnated in a dip pan and then sent through squeeze rolls or through slot dies to achieve the thickness requirements. The viscosity of the varnish can range from about 50 CPs to about 1500 CPs depending on the filler content and desired thickness.

The process of manufacture generally includes the use of horizontal or vertical treaters. The horizontal ovens are typically float-on-air/air floatation, while the vertical ovens are usually infrared or convection with air impingement. Horizontal treating is preferred, due to the lower wet strength of fabrics. For better thickness control, slot die, doctor blade, gravure, or other techniques are used. The temperature for treating can be between 100 to 200° C. with about 150° C. to about 175° C. preferred. The oven temperature range is typically over 150° C. at the hottest sections. The temperature profile and speed may be adjusted in accordance with the boiling range of the solvents.

In accordance with one or more embodiments, the dielectric material layer may be b-staged or c-staged upon cure. The dielectric material layer may be a prepreg or laminate.

In some embodiments, the dielectric material layer may be clad, e.g., copper clad.

In some embodiments, the dielectric material layer can be laminated onto copper foil to facilitate easy application for printed circuit board fabrication. In optional embodiments the prepreg is supported by a release or carrier film such as PET. In at least some embodiments, the web may be substantially unsupported.

Printed circuit boards are of many types ranging from single sided to double-sided to multilayer boards. A single lamination multilayer printed circuit board (PCB) is built by layering multiple sheets of copper-clad fiberglass or other insulating substrate material together, with each layer containing a different pattern of conductive traces and vias that interconnect the components and circuits on the board. The basic steps involved in building a multilayer PCB are as follows. The PCB design is created using computer-aided design (CAD) software. The design specifies the number of layers required, the layout of the circuitry, the location and size of the components, and the placement of the vias. Copper clad laminates (cores) are coated with a photo resistive material. The PCB design is printed onto the photoresistive material, and the unwanted areas are exposed to UV light. The exposed areas are then chemically etched away, leaving only the copper traces and vias. Once all the layers have been created, they are aligned and bonded together using the prepreg layers/bonding sheets. Small holes are drilled through the board at the locations where the vias are needed to connect the layers. The holes are plated with copper to create a conductive connection between the layers. The outer layers are then chemically etched to remove the unwanted copper and coated with a protective solder mask and silk screen to identify the component locations and other information. The board is cut to its final size, and any necessary finishing processes, such as surface plating, are applied.

High density interconnect (HDI) boards differ from single lamination type boards. The process of making HDI board depends on the type of the HDI board. Typically, different types of HDI boards depend on the type and number of sequential layers. Different types of HDI boards include 1+n+1, or i+n+I-when n=2, then it is called anylayer HDI process. The layers are built sequentially. In an anylayer process, the central core is processed and plated, followed by lamination with a dielectric layer comprising of a prepreg and copper on either side. The copper thickness may vary from a few microns to 18 microns where a subtractive etching process is used. The subtractive technology is suitable for boards that have lines and spacings more than typically 50 microns. For thinner lines and spacings as in advanced mobile devices and for chip packaging the lamination may be done without copper or with ultrathin copper on a carrier. The process is followed by etching of the copper and laser drilling, hole filling and plating. The next set of layers are built up after that. When thinner lines, typically below 50 microns, are required, either a mSAP (modified semi additive process) or, for still thinner lines below 25 microns, a semi additive process is used. In modified semi additive process or mSAP, a very thin layer of copper is laminated with the prepreg layer. The typical thickness of the foil ranges from 2-5 microns. Once this seed copper or base copper is in place, standard photolithography techniques are used to create the circuit and then the circuitry is plated up to the desired thickness. The resist can then be stripped, and panel is flash etched to remove the excess copper.

The semi additive process may or may not require a copper base layer. The lamination can be done without copper or using prepreg that has sputtered copper layers. The seed layer can then be deposited using the using an electroless process. The standard lithography processes are used in conjunction with develop etch and strip processes to create the circuit pattern, this is followed by subsequent steps familiar to one in the art. The present invention is easy to implement in the HDI process using the LCP reinforced prepregs of laminates. The layers do not require a support or a carrier, though carriers may be used. There is no need for vacuum dry lamination as is required for using films, which need to be vacuum laminated onto the board. The present invention allows the manufacturer to proceed directly to the press lamination.

In accordance with one or more embodiments, preparation of a printed circuit board may be facilitated by providing at least one dielectric material layer comprising a LCP reinforced substrate, the at least one dielectric material layer having a thickness of less than about 100 microns. Instructions may be provided for integrating the at least one dielectric material into the printed circuit board.

In accordance with one or more embodiments, various components may include a printed circuit board as described herein, for example, a high density interconnect (HDI) board, a high speed board, a high frequency board or chip packaging substrate.

The function and advantages of these and other embodiments can be better understood from the following examples. These examples are intended to be illustrative in nature and are not considered to be limiting the scope of the invention.

### Examples

Various resin formulations were prepared, and a number of different LCP reinforcements of different thickness were treated/impregnated with the formulations and pressed. The pressed laminates were tested for a number of properties including thickness, Tg, Modulus, DK and DF.

PPE resin (SA9000) was dissolved in Toluene, Styrene Butadiene resin and TAIC were added next followed by the flame retardants, Silica was added after Dicup. The resin was used to impregnate non-woven fabric and the fabric was dried at 150° C. for 4 minutes in a Class A oven. The material was pressed at 225° C. for 2 hours.

The various formulation details are presented below.

Example 1

| Ingredients | Ex. 1 | % |
|---|---|---|
| PPE | 8.00 | |
| TAIC | 6.00 | |
| OP 945 | 3.53 | |
| Styrene Butadiene Resin | 6.00 | |
| Spherical Silica | 24.01 | 50% |
| Dicup | 0.40 | |
| Toluene | 32.06 | |
| Total | 80.00 | |

Example 2

| Ingredients | Ex. 2 | % |
|---|---|---|
| PPE | 10.08 | |
| TAIC | 6.00 | |
| OP 945 | 4.41 | |
| Styrene Butadiene Resin | 9.00 | |
| Spherical Silica | 10.01 | 25% |
| Dicup | 0.50 | |
| Toluene | 40.00 | |
| Total | 80.00 | |

Example 3

| Ingredients | Ex. 3 | % |
|---|---|---|
| PPE | 13.44 | |
| TAIC | 8.00 | |
| OP 945 | 5.89 | |
| Styrene Butadiene Resin | 12.00 | |
| Spherical Silica | — | 0% |
| Dicup | 0.68 | |
| Toluene | 40.00 | |
| Total | 80.00 | |

Example 4

| Ingredients | Ex. 4 | % |
|---|---|---|
| PPE | 6.80 | |
| TAIC | 1.80 | |
| OP 945 | 3.00 | |
| Styrene Butadiene Resin | 6.00 | |
| Spherical Silica | 30.00 | 62% |
| Dicup | 0.40 | |
| Toluene | 32.00 | |
| Total | 80.00 | |

The formulations were run with different ingredients in a Class A oven. The summary of the properties is given below.

TABLE 1
Summary of Properties

| | LCP | Resin | Thickness | DK @10 GHz | DF @10 GHz | Tg- | Modulus |
|---|---|---|---|---|---|---|---|
| Example | Gsm | Content | Microns | SPDR | SPDR | DMA ° C. | Tensile GPa |
| 1 | 6 | 78.5% | 20.02 | 2.67 | 0.0020 | 181 | 7.20 |
| 1 | 9 | 81.4% | 34.49 | 2.98 | 0.0019 | 183 | 5.80 |
| 2 | 6 | 82.7% | 24.97 | 2.76 | 0.0020 | 186 | 5.60 |
| 2 | 9 | 82.9% | 37.80 | 2.83 | 0.0020 | 192 | 5.40 |
| 3 | 4 | 82.1% | 15.12 | 2.85 | 0.0020 | 200 | 5.70 |
| 3 | 6 | 81.6% | 22.08 | 2.88 | 0.0022 | 202 | 6.00 |
| 3 | 9 | 80.4% | 31.15 | 2.92 | 0.0023 | 202 | 6.30 |
| 3 | 25 | 70.3% | 58.06 | 3.20 | 0.0035 | 193 | 7.30 |
| 4 | 4 | 88.5% | 23.28 | 2.96 | 0.0019 | 222 | 6.40 |
| 4 | 6 | 89.0% | 36.47 | 2.98 | 0.0019 | 224 | 6.60 |

This data demonstrates that very low thickness can be achieved in accordance with one or more disclosed embodiments. Beneficially, the DK and DF values were very well suited to the requirements of specific applications as discussed herein. The Tg value was higher than 150° C. and the modulus (and thus stiffness) was much higher than those of conventional films. The materials are therefore highly suitable for high speed, HDI and chip packaging applications.

The phraseology and terminology used herein is for the purpose of description and should not be regarded as limiting. As used herein, the term “plurality” refers to two or more items or components. The terms “comprising,” “including,” “carrying,” “having,” “containing,” and “involving,” whether in the written description or the claims and the like, are open-ended terms, i.e., to mean “including but not limited to.” Thus, the use of such terms is meant to encompass the items listed thereafter, and equivalents thereof, as well as additional items. Only the transitional phrases “consisting of” and “consisting essentially of,” are closed or semi-closed transitional phrases, respectively, with respect to the claims. Use of ordinal terms such as “first,” “second,” “third,” and the like in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Having thus described several aspects of at least one embodiment, it is to be appreciated that various alterations, modifications, and improvements will readily occur to those skilled in the art. Any feature described in any embodiment may be included in or substituted for any feature of any other embodiment. Such alterations, modifications, and improvements are intended to be part of this disclosure and are intended to be within the scope of the invention. Accordingly, the foregoing description and drawings are by way of example only.

Those skilled in the art should appreciate that the parameters and configurations described herein are exemplary and that actual parameters and/or configurations will depend on the specific application in which the disclosed methods and materials are used. Those skilled in the art should also recognize or be able to ascertain, using no more than routine experimentation, equivalents to the specific embodiments disclosed.

What is claimed is:

1. A printed circuit board, comprising:
at least one dielectric material layer comprising a thermoplastic liquid crystal polymer (LCP) nonwoven fabric impregnated with a thermosetting resin having a dissipation factor (DF) of less than 0.010 at 10 GHz and a filler content of at least 20% by weight, wherein the at least one dielectric material layer has a thickness of less than 100 microns and a dielectric constant (DK) value of less than 3.4, and wherein the at least one dielectric material layer is characterized by a glass transition temperature (Tg) of greater than 150° C. and a tensile modulus in plane directions of greater than 5 GPa.

2. (canceled)

3. The printed circuit board of claim 1, wherein the at least one dielectric material layer has a DK value of less than 3.0.

4. The printed circuit board of claim 3, wherein the at least one dielectric material layer has a DK value of less than 2.8.

5. The printed circuit board of claim 1, wherein the at least one dielectric material layer is characterized by a dissipation factor of less than 0.005 at 10 GHz.

6. The printed circuit board of claim 5, wherein the at least one dielectric material layer is characterized by a dissipation factor of less than 0.0025 at 10 GHz.

7. (canceled)

8. The printed circuit board of claim 1, wherein the at least one dielectric material layer has a thickness of less than 50 microns.

9. The printed circuit board of claim 8, wherein the at least one dielectric material layer has a thickness of less than 40 microns.

10. The printed circuit board of claim 9, wherein the at least one dielectric material layer has a thickness of less than 25 microns.

11. The printed circuit board of claim 1, wherein the at least one dielectric material layer comprises a prepreg or a laminate.

12. The printed circuit board of claim 1, wherein the thermosetting resin is a crosslinked thermosetting polymer resin selected from the group consisting of: an epoxy resin, a bismaleimide resin, a cyanate ester resin, a bismaleimide-triazine (BT) resin, a polybutadiene resin and a polyphenylene ether (PPE)/poly(p-phenylene oxide) (PPO) resin.

13. The printed circuit board of claim 1, wherein the thermosetting resin is a crosslinked thermosetting polymer resin comprising at least one resin selected from the group consisting of: a vinyl functional PPE resin, an oligophenylene ether (OPE) resin, a Bismaleimide resin, a Triallyl Cyanurate resin and a Tri Allyl Isocyanurate resin.

14. The printed circuit board of claim 1, wherein the thermosetting resin is substantially halogen free.

15. The printed circuit board of claim 13, wherein the thermosetting resin further comprises at least one of: a flame retardant, a curing agent, a hardener, a filler and an additive.

16. The printed circuit board of claim 1, wherein the at least one dielectric material layer is copper clad.

17. The printed circuit board of claim 1, wherein the LCP nonwoven fabric comprises a polyarylate resin.

18. The printed circuit board of claim 1, wherein the LCP nonwoven fabric is characterized by a basis weight of less than 25 GSM.

19. The printed circuit board of claim 18, wherein the LCP nonwoven fabric is characterized by a basis weight of less than 10 GSM.

20-21. (canceled)

22. The printed circuit board of claim 1, wherein the printed circuit board is a high density interconnect (HDI) printed circuit board.
